(19) United States
(12) Patent Application Publication
(10) Pub. No.: US 2015/0070444 A1
(43) Pub. Date: Mar. 12, 2015

(54) PIEZOELECTRIC ACTUATOR, FLUID DISCHARGE HEAD, AND IMAGE FORMING DEVICE

(71) Applicants: Masahiro Ishimori, Tokyo (JP); Manabu Nishimura, Kobe-shi (JP); Masaru Shinkai, Yokohama-shi (JP); Keiji UEDA, Kawasaki-shi (JP); Tsutoh Aoyama, Atsugi-shi (JP); Toshiaki Masuda, Atsugi-shi (JP)

(72) Inventors: Masahiro Ishimori, Tokyo (JP); Manabu Nishimura, Kobe-shi (JP); Masaru Shinkai, Yokohama-shi (JP); Keiji UEDA, Kawasaki-shi (JP); Tsutoh Aoyama, Atsugi-shi (JP); Toshiaki Masuda, Atsugi-shi (JP)

(73) Assignee: RICOH COMPANY, LTD., Tokyo (JP)

(21) Appl. No.: 14/469,700

(22) Filed: Aug. 27, 2014

(30) Foreign Application Priority Data
Sep. 11, 2013 (JP) 2013-187818
Jul. 3, 2014 (JP) 2014-137441

(51) Int. Cl. H01L 41/047; H01L 41/25; B41J 2/175; H01L 41/09; B41J 2/14

(52) U.S. Cl. CPC H01L 41/0477; H01L 41/09; B41J 2/14201; B41J 2/17503; H01L 41/25; Y10S 977/837; B82Y 15/00
USPC 347/68; 310/328; 347/87; 29/25.35; 977/837

(57) ABSTRACT

A piezoelectric actuator includes a vibrating plate, a lower electrode provided on the vibrating plate, including a platinum film and a titanium oxide film formed on the platinum film, a piezoelectric thin film provided on the lower electrode, and an upper electrode provided on the piezoelectric thin film, in which the titanium oxide film is provided between the platinum film and the piezoelectric thin film.

### CROSS REFERENCE TO RELATED APPLICATION

The present application is based on and claims priority from Japanese Patent Application No. 2013-187818, filed on Sep. 11, 2013 and No. 2014-137441, filed on Jul. 3, 2014, the disclosure of which is hereby incorporated by reference in its entirety.

### BACKGROUND OF THE INVENTION

1. Field of the Invention

The present invention relates to a piezoelectric actuator, a fluid discharge head incorporating the piezoelectric actuator, and an image forming device incorporating the fluid discharge head.

2. Description of the Related Art

In general an image recording device such as printer, facsimile machine, and photocopier comprises an ink jet head as a fluid discharge head. The ink jet head includes a nozzle to discharge drops of ink, a pressure chamber in which ink is accumulated, a vibrating plate forming a part of the walls of the pressure chamber, and an electromechanical transducer to apply pressure to the ink in the pressure chamber. The electromechanical transducer is driven to pressurize the pressure chamber via the vibrating plate and discharge ink drops from the nozzle.

For example, two kinds of a piezoelectric ink jet head are known. One uses a piezoelectric actuator with a vertical vibration mode in which the actuator is extended/shrunk along the axis of the electromechanical transducer and the other uses a piezoelectric actuator with a bend mode. A thin-film piezoelectric actuator, which is the latter piezoelectric actuator reduced in thickness, is a thin-film device comprised of laminated membranes formed by repeatedly forming various thin layers and patterning on a substrate.

The crystallization of the piezoelectric thin film is affected by crystal orientation of a substrate as a base or a lower electrode. The interface between the lower electrode and a PZT (lead zirconate titanate) film is particularly susceptible. In order to achieve a high piezoelectric constant, it is important that the piezoelectric thin film exerts plane orientation of (100).

Japanese Laid-open Patent Application Publication No. H11-191646 discloses a piezoelectric actuator comprising a silicon oxide film, a titanium oxide film, a lower electrode, a piezoelectric thin film, and an upper electrode laminated on a silicon substrate from bottom to top in this order. In this actuator the lower electrode is made from platinum, and titanium to be the crystal of a piezoelectric material is formed in an island shape in the crystal grain boundary of the platinum.

Further, the lower electrode is comprised of a titanium oxide film, platinum, and titanium laminated on the vibrating plate from bottom to top. The titanium oxide film is used to enhance the adherence between the vibrating plate and the lower electrode and it is an adherent layer. There is a problem with using a titanium oxide film as an adherent layer in that minute holes of 100 nm or less occur in the lower electrode film and on the surface of the lower electrode after thermal oxidation or PZT calcination. That is, in the thermal oxidation or PZT calcination titanium is diffused in a platinum film, causing the formation of holes in the platinum film.

The holes in the platinum film hinder continuity of platinum crystal so that it is hard to enlarge the mean particle diameter of the piezoelectric thin film formed thereon. The crystallinity of platinum and titanium oxide affects the quality of the piezoelectric thin film or piezoelectric material formed thereon. Because of this, the piezoelectric actuator containing the piezoelectric material cannot exert sufficient piezoelectric properties, which results in lowering manufacturing reproducibility thereof.

Further, lead components of the PZT film are excessively trapped in the holes on the lower electrode surface and the platinum film. Excessively diffused lead in the lower electrode causes the formation of a leak path or electric field concentration, which leads to decreasing the voltage holding capabilities of the piezoelectric actuator. This causes another problem that a decrease in a drop speed of the fluid discharge head is accelerated.

### SUMMARY OF THE INVENTION

The present invention aims to provide a piezoelectric actuator with good piezoelectric properties including a dense pillar-structured film with no holes in a lower electrode.

According to one embodiment, a piezoelectric actuator comprises a vibrating plate, a lower electrode provided on the vibrating plate, including a platinum film and a titanium oxide film formed on the platinum film, a piezoelectric thin film provided on the lower electrode, and an upper electrode provided on the piezoelectric thin film, wherein the titanium oxide film is provided between the platinum film and the piezoelectric thin film.

### BRIEF DESCRIPTION OF THE DRAWINGS

Features, embodiments, and advantages of the present invention will become apparent from the following detailed description with reference to the accompanying drawings:

FIG. 1 is a schematic cross section view of a piezoelectric actuator according to a first embodiment;

FIG. 2 is a cross section view of the piezoelectric actuator with a lower electrode of an electromechanical transducer shown in detail;

FIG. 3 is a cross section view of an ink jet head according to a second embodiment;

FIG. 4 is a photographic view of a cross section of the periphery of the lower electrode of the piezoelectric actuator;

FIG. 5 is a perspective view of a fluid cartridge according to a third embodiment;

FIG. 6 is a perspective view of an image forming device; and

FIG. 7 is a vertical cross section view of the image forming device in FIG. 6.

### DETAILED DESCRIPTION OF THE PREFERRED EMBODIMENTS

Hereinafter, embodiments of the present invention will be described in detail with reference to the accompanying drawings. Wherever possible, the same reference numbers will be used throughout the drawings to refer to the same or like parts.

### First Embodiment

A piezoelectric actuator according to the present embodiment comprises an electromechanical transducer comprised of a lower electrode, a piezoelectric thin film, and an upper electrode. The lower electrode is laminated on a titanium oxide adherent layer formed on the top side of the vibrating plate.

The lower electrode is a dense film free from minute holes of 100 am or less and comprises a platinum film formed on the titanium oxide adherent layer and a titanium oxide film on the platinum film.

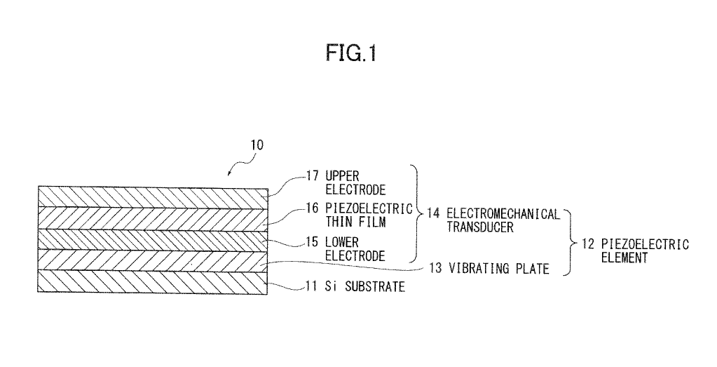

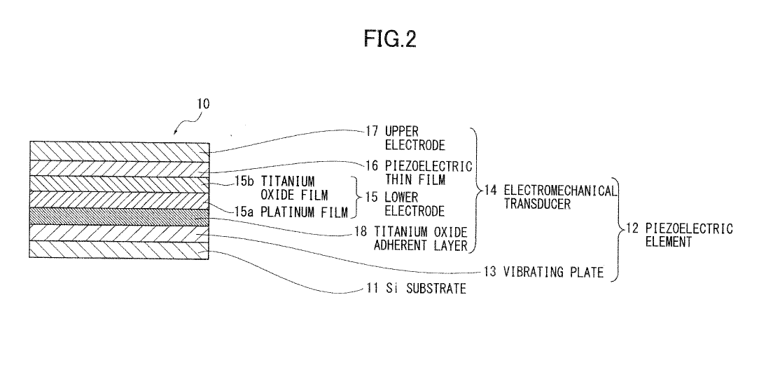

FIGS. 1 and 2 show a piezoelectric actuator 10 according to the present embodiment. FIG. 1 is a schematic cross section view of the piezoelectric actuator and FIG. 2 is the same showing the lower electrode of the electromechanical transducer in detail

In FIG. 1 the piezoelectric actuator 10 comprises a substrate 11 and a piezoelectric element 12 formed on the substrate 11.

The piezoelectric element 12 comprises a vibrating plate 13 laminated on the substrate 11 and an electromechanical transducer 14 provided on the vibrating plate 13. The electromechanical transducer 14 comprises a lower electrode 15, a piezoelectric thin film 16, and an upper electrode 17 laminated on the vibrating plate 13 in this order from bottom to top.

In the present embodiment a titanium oxide adherent layer 18 is formed on the vibrating plate 13 and the electromechanical transducer 14 is formed on the titanium oxide adherent layer 18, as shown in FIG. 2. The lower electrode 15 of the electromechanical transducer 14 includes a platinum film or platinum electrode 15a and a titanium oxide film 15b on the platinum film 15a. The upper electrode 17 is formed on the piezoelectric thin film 16.

As described above, the lower electrode 15 of the piezoelectric actuator 10 according to the present embodiment includes the platinum film 15a and the titanium oxide film 15b, and the titanium oxide film 15b is provided between the platinum film 15a and the piezoelectric thin film 16.

The platinum film 15a includes Pt (111) crystal. By providing the titanium oxide film 15b on this platinum film 15a as a buffer layer, the piezoelectric thin film 16 acquires PZT (100) crystallinity. As a result, PZT (100) preferred crystal orientation can be 90% or more.

Meanwhile, generally, a film with PZT (111) preferred orientation is formed by directly laminating the piezoelectric thin film 16 on the platinum film 15a formed on the titanium oxide adherent layer 18. Accordingly, the PZT (100) preferred crystal orientation cannot be increased.

Next, a manufacturing method of the piezoelectric actuator 10 as configured above will be described, referring to FIG. 2.

First, a silicon substrate made from silicon (Si) is prepared for the substrate 11. Then, the surface of the substrate 11 is thermally oxidized to create a SiO₂ insulating film thereon. The SiO₂ insulating film is the vibrating plate 13. The thickness of the SiO₂ insulating film is 2 μm.

Next, a titanium film is formed on the SiO₂ insulating film by sputtering and subjected to thermal oxidation in O₂ atmosphere for 1 to 10 minutes at temperature of 650 to 800 C by use of a RTA (Rapid Thermal Annealing) device to form a titanium oxide film. Thereby, the titanium oxide adherent layer 18 is formed on the vibrating plate 13. Preferably, the thickness of the titanium oxide film should be 20 to 50 nm. The titanium oxide film can be created by reactive sputtering, however, thermal oxidation of a titanium film at a high temperature is more preferable.

The platinum film (platinum electrode) 15a of the lower electrode 15 is formed on the titanium oxide adherent layer 18 by sputtering.

Then, the titanium oxide film 15b is formed on the platinum film 15a by forming a titanium film by sputtering and subjected to thermal oxidation in O₂ atmosphere for 1 to 5 minutes at temperature of 650 to 800 C (particularly, 700 to 750 C) by use of the RTA device. By thermal oxidation at 700 to 750 C, the titanium film can be oxidized to the interface with the platinum film 15a so that a good titanium oxide film can be obtained. The thickness of the titanium oxide film 15b should be preferably 50 to 100 angstrom (A) to form a PZT film (PZT(100) film) having crystallinity (100) with good piezoelectric properties. The titanium oxide film 15b can be created by reactive sputtering, however, thermal oxidation of a titanium film at a high temperature is more preferable. Further, the crystallinity of the titanium oxide film (TiO₂ film) is enhanced by thermal oxidation with the RTA device than with a general heating furnace. This is because by oxidization with a heating furnace, an easily-oxidized titanium film forms a number of crystal structures at a low temperature. Thus, by use of the RTA device which can rapidly raise temperature, good crystal can be obtained.

Next, to create the piezoelectric thin film 16, a solution mixed at a composition ratio of Pb (lead):Zr (zirconium):Ti (titanium)=110:53:47 is prepared. For synthesizing precursor embrocation of this solution, specifically, lead (II) acetate rehydrate, isopropoxide titanate, and zirconium (IV) isopropoxide are used as a starting material. Crystal water of the lead acetate is dissolved in methoxyethanol and dehydrated. Herein, the amount of the lead is excessively prepared relative to stoichiometric composition for the purpose of preventing a deterioration in the crystallinity due to evaporation of lead during a thermal process.

The isopropoxide titanate and zirconium (IV) isopropoxide are dissolved in methoxyethanol, subjected to alcohol exchange and etherification, and mixed with the methoxyethanol solution in which the lead(II) acetate is dissolved. Thereby a PZT precursor solution is synthesized. The PZT concentration of this solution is 0.5 mol/liter. A film is formed from this solution by spin coating, dried at 120 C, and subjected to thermal decomposition at 500 C. Then, after the third layer is thermally discomposed, the film is subjected to crystallization heat treatment by RTA at the temperature of 750 C. The thickness of the PZT is 250 nm. By repeating the above process eight times (24 layers), a PZT film in thickness of about 2 μm is acquired.

Then, a platinum film is formed as the upper electrode 17 by sputtering. The material of the upper electrode 17 is not limited to platinum. Alternatively, a metal electrode such as iridium or gold can be used or a laminated film of oxide electrode layer and metal electrode layer can be used. IrO₂, LaNiO₃, RuO₂, SrO, and SrRuO₃ are used for the oxide electrode layer and platinum, iridium, and gold are used for the metal electrode layer.

The piezoelectric actuator 10 in FIG. 2 is manufactured in the above manner. The piezoelectric actuator 10 is comprised of the substrate 11, vibrating plate 13, titanium oxide adherent layer 18, platinum film 15a, titanium oxide film, piezoelectric thin film 16, and upper electrode 17 laminated in this order.

As described above, minute holes are prevented from occurring on the platinum film 15a, titanium oxide film 15b, and piezoelectric thin film 16 by oxidizing titanium (Ti) by rapid thermal annealing.

Meanwhile, without the titanium oxide film 15b, the minute holes in the platinum film 15a make it hard to increase the mean particle diameter of the piezoelectric thin film 16 provided on the platinum film 15a.

According to the present embodiment, by forming the titanium oxide adherent layer 18 on the vibrating plate 13, the lower electrode 15 (platinum film 15a and titanium oxide film 15b) in a dense pillar structural film with no minute holes can be formed. Note that the minute holes are ones of 100 nm or less.

Further, the inventors of the present application have found that provided with the titanium oxide film 15b on the side of the lower electrode 15 close to the piezoelectric thin film 16, the crystal orientation of the piezoelectric thin film 16 becomes (100). Also, the PZT (100) orientation can be improved by thermally oxidizing the titanium film at 650 C or more.

Thus, by thermally oxidizing the titanium film at 650 C or more, it is able to realize a dense pillar-structured film having no minute holes in the lower electrode 15 with a good, stable reproducibility even after the thermal oxidation.

Diffusion of titanium in the platinum film 15a during the thermal oxidation and PZT calcination causes the creation of holes therein. This can be prevented by completely oxidizing the titanium film (that is, titanium oxide adherent layer 18) on the vibrating plate 13. Owing to the titanium oxide adherent layer 18, in forming the side of the titanium oxide film 15b close to the piezoelectric thin film 16, titanium is prevented from dispersing in the platinum film 15a. Specifically, the titanium oxide adherent layer 18 is formed by forming the titanium film by sputtering. Then, the titanium film is thermally oxidized in O₂ atmosphere at 650 C or more with the RTA device, thereby improving the crystallinity of the platinum film 15a while maintaining the adherence.

Further, without the holes, the continuity of platinum crystal in the platinum film 15a is not hindered so that the mean particle diameter of the piezoelectric thin film 16 formed thereon can be increased from that of a conventional piezoelectric thin film of titanium oxide, platinum, and titanium layers. Accordingly, the piezoelectric actuator 10 can exert a good manufacturing reproducibility and sufficient piezoelectric properties.

Further, according to the present embodiment since the piezoelectric thin film 16 has crystallinity of 100, the piezoelectric constant of the piezoelectric element 12 can be enhanced.

Moreover, an excellent PZT(100) film can be produced by forming the titanium oxide film 15b by thermal oxidation to the titanium film formed on the platinum film 15a by RTA. Thus, the properties of the piezoelectric thin film 16 can be improved.

### Second Embodiment

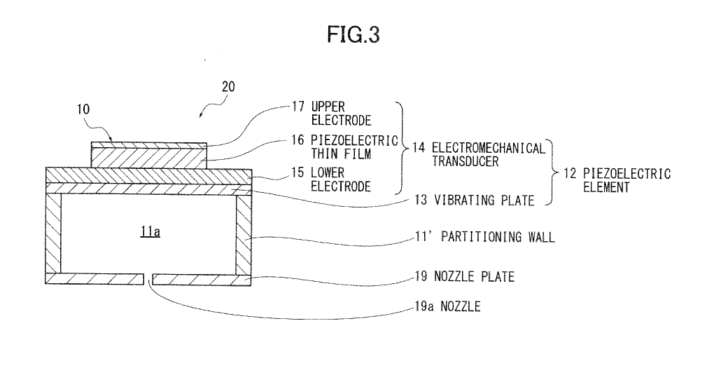

FIG. 3 shows an example of an ink jet head as a fluid discharge head incorporating the piezoelectric actuator 10 according to the first embodiment.

An ink jet head 20 according to a second embodiment includes partition walls 11′ on the four sides at the bottom although front and back walls are not shown. The four partition walls 11′ form a barrel shape with a rectangular transverse cross section. The vibrating plate 13 and a nozzle plate 19 including a nozzle 19a are secured on the top and bottom end faces of the partition walls, respectively. The nozzle plate 19 encloses the opening ends of the partitioning walls 11′. A pressure chamber 11a in which ink is temporarily stored is formed in a space surrounded by the partitioning walls 11′, vibrating plate 13, and nozzle plate 19. By deforming the vibrating plate 13 with pressure, the ink is discharged from the pressure chamber 11a through the nozzle 19a of the nozzle plate 19.

In the ink jet head 20 in FIG. 3 the partitioning walls 11′ and nozzle plate 19 are provided below the piezoelectric element 12 while in the piezoelectric actuator in FIG. 2 the substrate 11 is provided therebelow. The partitioning walls 11′ and nozzle plate 19 are produced by processing the substrate 11, as described below.

A silicon single-crystal substrate in thickness of 100 to 650 μm is preferable for the substrate 11. To create the pressure chamber 11a in FIG. 3, the substrate 11 is processed by anisotropic etching.

To apply the piezoelectric element 12 to the ink jet head 20 in FIG. 3, the pressure chamber 11a is formed in the substrate 11. Also, the vibrating plate 13 preferably has certain strength since it is deformed to discharge ink drops in the pressure chamber 11a, upon receiving a force from the piezoelectric thin film 16.

A material of the vibrating plate as a base can be one made from Si, SiO₂, Si₃N₄ by chemical vapor deposition (CVD) method. Moreover, it is preferable to use a material with a linear expansion coefficient close to that of the lower electrode 15 and piezoelectric thin film 16. In particular the use of a material with a linear expansion coefficient of 5×10⁻⁶ to 10×10⁻⁶[1/K] close to 8×10⁻⁶[1/K] of PZT is preferable since the piezoelectric thin film 16 is generally made from PZT. A material with a linear expansion coefficient of 7×10⁻⁶ to 9×10⁻⁶ [1/K] is more preferable. Specifically, aluminum oxide, zirconium oxide, iridium oxide, ruthenium oxide, tantalum oxide, hafnium oxide, osmium oxide, rhenium oxide, rhodium oxide, palladium oxide and compounds of these oxides are exemplified. The vibrating plate 13 can be created from these materials with a spin coater by sputtering or sol-gel method. The thickness thereof should be preferably 0.1 to 10 μm, more preferably 0.5 to 3 μm. With a thickness below these ranges, it is difficult to process the pressure chamber 11a while with a thickness exceeding the ranges, the base is not easily deformed so that ink drops cannot be stably discharged.

Next, a titanium film in thickness of 20 to 50 nm is formed on the vibrating plate 13 before the lower electrode 15.

Then, the titanium film is subjected to thermal oxidation in O₂ atmosphere for 1 to 10 minutes at 650 to 800 C by use of the RTA device to create the titanium oxide adherent layer 18 or titanium oxide film on the vibrating plate 13.

The titanium oxide film can be created by reactive sputtering, however, the thermal oxidation of the titanium film at a high temperature is more preferable. To create the titanium oxide film by reactive sputtering, a special sputtering chamber structure is required because a silicon substrate needs to be heated at a high temperature. Further, the crystallinity of the titanium oxide film is enhanced by the thermal oxidation with the RTA device than with a general heating furnace. This is because an easily-oxidized titanium film forms a number of crystal structures at a low temperature by oxidization with a heating furnace. Thus, by use of the RTA device which can rapidly raise temperature, good crystal can be obtained.

Next, the platinum film or platinum electrode 15a (FIG. 2) of the lower electrode 15 is formed in thickness of 200 am or less on the titanium oxide adherent layer 18 by sputtering.

Then, the titanium oxide film 15b (FIG. 2) is formed on the platinum film 15a. That is, a titanium film is formed thereon by sputtering and subjected to thermal oxidation in 02 atmosphere for 1 to 5 minutes at 650 to 800 C by use of the RTA device. The thickness of the titanium oxide film should be preferably in the range of 30 to 70 angstrom (A), to realize a PZT (100) film with good piezoelectric properties. It is preferable to produce the titanium oxide film by high-temperature thermal oxidation. Further, the crystallinity of the titanium oxide film is enhanced by the thermal oxidation with the RTA device than with a general heating furnace. This is because an easily-oxidized titanium film forms a number of crystal structures at a low temperature by oxidization with a heating furnace. Thus, by use of the RTA device which can rapidly raise temperature, good crystal can be obtained.

The piezoelectric thin film 16 is chiefly made from PZT (Lead Titanate Zirconate) at a ratio of zirconium (Zr) and titanium (Ti), 52 to 48, due to its stable and good piezoelectric performance and properties. Lead titanate zirconate is, however, not limited to the above compound. Alternatively, various oxides containing lead, zirconium, and titanium at different ratios or mixed with or replaced with an additive can be used. Also, perovskite oxides with a general formula of ABO₃ (A including Pb, B including Zr and Ti) are suitably used, for example. Niobic acid titanic acid zirconic acid lead using (PZTN) Nb is well known. Moreover. In view of environmental concerns, barium titanate (BaTiO₃) with no use of Pb, a complex oxide (BST) of barium, strontium and titanium, and a complex oxide of strontium, bismuth and tantalum can be used.

The piezoelectric thin film 16 is manufactured by sol-gel method, that is, spin coating of sol-gel. For example, in the case of PZT, organic metal compounds containing Pb, Zr, Ti are dissolved in a solution and coated on the film of the lower electrode 15. The coated piezoelectric film is subjected to calcinations for solidifying and crystallization. Thereby, the piezoelectric thin film 16 can be created. The calcination for solidifying is in general conducted for every coated layer while that for crystallization is collectively conducted for every several solidified layers. A piezoelectric layer in a desired thickness can be obtained through repetition of a series of the calcinations for solidification and crystallization. It is dried at temperature of 350 to 550 C and heated at about 650 to 800 C for crystallization. By use of the RTA device, heating time is several seconds to several minutes. The thickness of the piezoelectric layer is for example several dozen nm to several μm.

The upper electrode 17 is formed on the piezoelectric layer or piezoelectric thin film 16. The upper electrode 17 can be made from the same material as that of the lower electrode 15. The material of the upper electrode layer 17 can be chosen from a larger number of materials than that of the lower electrode 15 since a high-temperature process and lattice constant matching necessary for forming the piezoelectric layer are unneeded. A platinum film and a metal electrode such as iridium or gold are usable for the upper electrode 17. A laminated layer of an oxide electrode layer and a metal electrode layer is also usable. For the oxide electrode layer, IrO₂, LaNiO₃, RuO₂, SrO, or SrRuO₃ can be used, for instance.

The upper electrode is chiefly formed by sputtering, however, it can be created by a known method such vacuum deposition and CVD (Chemical Vapor Deposition). The thickness of the upper electrode 17 can be in the range of about 50 to 300 nm. In general the piezoelectric thin film 16 is formed after the lower electrode 15 and the upper electrode 17 is formed on the piezoelectric thin film 16.

The piezoelectric thin film 16 is generally formed on the lower electrode 15 by dry or wet etching after an etching mask layer is formed thereon by patterning of a photosensitive resist.

Then, another piezoelectric element is formed after the upper electrode 17. It is formed on the upper electrode 17 by dry or wet etching after an etching mask layer is formed thereon by patterning of a photosensitive resist. The photosensitive resist is patterned by a known photo-lithography. That is, a photosensitive resist is coated on a specimen substrate with a spin coater or roll coater and exposed to an ultraviolet ray by a glass photo mask having a desired pattern. Thereafter, the pattern is developed, and the substrate is washed with water and dried to form a photosensitive resist mask layer. The end of the patterning of the photosensitive resist mask layer is tilted, which affects an inclined section thereof at the time of etching. It is selected in accordance with a desired tilt angle with a resist selection ratio (ratio of etching rates between etched material and masking material) taken into account. A residual photosensitive resist on the film after etching can be removed by a dedicated peeling fluid or oxygen plasma ashing.

Because of a shape stability, dry etching using reactive gas is adopted. However, halogenous gas including chlorine or fluorine gas, or halogenous gas mixed with Ar or oxygen can be also used. By changing etching gas or etching condition, the upper electrode 17 and piezoelectric element can be continuously etched or resist patterning can be repeated to separately conduct etching at several times.

Although not shown, a protective layer is disposed to shield the piezoelectric thin film 16 placed between the electrodes and a cross section thereof forming the shape of the film from a driving condition such as humidity. The protective layer is made from oxide by atomic layer deposition (ALD) in view of required density. Specifically, an ALD film of Al₂O₃ in thickness of about 30 to 100 nm is used.

Further, although not shown, an insulating layer is formed on the upper electrode 17 to insulate between a wired electrode laminated in the next process and the upper and lower electrodes 17, 15. It is made from a silicon dioxide film, a silicon nitride film, or a mixed film of the two. The thickness thereof is 300 to 700 nm.

A through hole is formed by photo lithography and etching in the wired electrode, upper electrode 17, and lower electrode 15 for contact. Residual resist is removed by oxygen plasma ashing, for example.

The wired electrode layer is used to fetch an individual or common electrode of a ferroelectric element and made from a material in ohmic contact with the upper and lower electrodes. Specifically, a wiring material containing pure Al or Al containing a hillock preventing component such as Si of several atomic % can be used. In view of conductivity, a semiconductor wiring material consisting mainly of Cu can be also used. The thickness of the layer is set to a value such that a wiring resistance including one due to a wiring distance does not trouble the driving of the piezoelectric element. Specifically, the thickness of an Al wiring should be set to about 1 μm. The wired electrode layer can be shaped as desired by photo lithography and residual resist is removed by oxygen plasma ashing, for example.

The wired electrode layer is covered with a protective layer of oxide or nitrade except for a portion for electric connection, in order to secure resistance to environment.

Lastly, an ink chamber is created by deeply cutting the Si substrate till the vibrating plate by inductively coupled plasma (ICP) etching. Thus, the substrate on which the piezoelectric actuator is formed is completed.

In the subsequent process the nozzle plate, a driver circuit, and an ink supplier are assembled to form the ink jet head.

### Comparison Example

For the purpose of comparison with the piezoelectric actuator according to the present embodiment, a piezoelectric actuator as a first example was created by forming the titanium film as the titanium oxide adherent layer by sputtering but without the RTA process. The particle diameter, withstand voltage and else were measured in the following manner. The results of measurement are described in the following.

TABLE 1

| | PARTICLE |
|---|---|
| | DIAMETER (nm) |
| FIRST EXAMPLE | 80~70 |
| FIRST EMBODIMENT | 120~200 |

The particle diameters of the two piezoelectric actuators according to the first embodiment and first example were evaluated immediately after the formation of a PZT film by use of an AFM (Atomic Force Microscope) Nanoscope IIIa manufactured by Veeco Instruments Inc. In the first example the AFM film configuration and the particle diameter thereof (nm) were evaluated.

The piezoelectric thin film of the first example was created in the same manner as in the first embodiment except for forming a titanium film by sputtering and not performing RTA process. The AFM was used in a tapping mode in the range of 3 μm×3 μm and scanning speed was 1 Hz. The results are shown in Table 1.

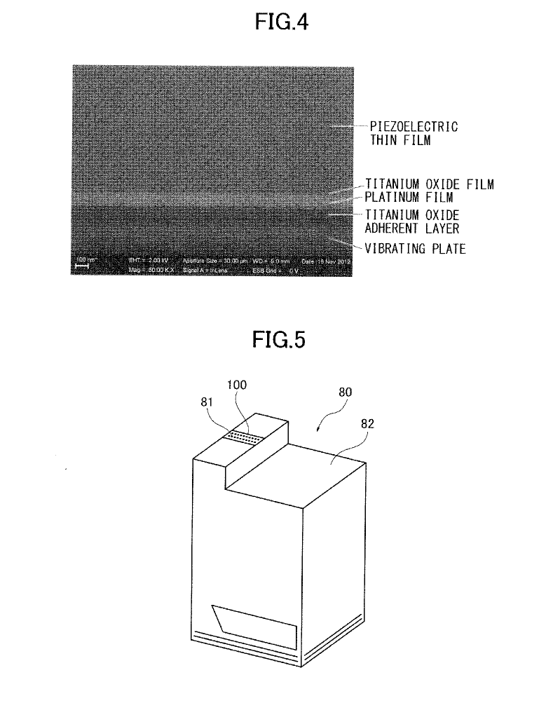

No holes were observed in the piezoelectric actuator according to the first embodiment. Meanwhile, the piezoelectric actuator of the first example contained a large number of holes on the platinum electrode. The lower electrode including the platinum film and titanium oxide adherent layer in the first embodiment was free from any holes after completion of the piezoelectric actuator, as shown in FIG. 4. To check the presence of holes, the cross section thereof along the thickness was processed by FIB (Focused Ion Beam) process and observed with a scanning electron microscope (SEM) with a magnification of 100 k or more.

The resistance to voltage (V), residual polarization Pr(μC/cm²), piezoelectric constant d31(pm/V), and degradation rate (%) of the piezoelectric thin films according to the first embodiment and first example were compared. The piezoelectric thin films were applied with electric field of 150 kV/cm and amounts of deformation were measured with a laser Doppler vibrometer. The measuring results were matched with simulation results for calculation. After evaluation of the initial properties, their durabilities (properties immediately after voltage was applied repeatedly at 10¹⁰ times) were evaluated. Table 2 shows the results.

TABLE 2

| | WITHSTAND | Pr (μC/cm²) | | d31 (pm/V) | | DEGRADATION |
|---|---|---|---|---|---|---|
| | VOLTAGE | INITIAL | AFTER | INITIAL | AFTER | RATE |
| | (V) | PERIOD | 1E10 TIMES | PERIOD | IE10 TIMES | (%) |
| FIRST | 204 | 50 | 48 | −180 | −178 | 2.7 |
| EMBODIMENT | | | | | | |
| FIRST | 101 | 44 | 36 | −140 | −126 | 11.2 |
| EXAMPLE | | | | | | |

As shown in Table 2, the obtained properties of the piezoelectric thin film according to the first embodiment are equivalent to those of a typical sintered ceramic element. That is, the resistance to voltage was 204V, residual polarization was 50 μC/cm², piezoelectric constant was −180 pm/V, and degradation rate (%) of ink drop speed was 2.7%.

Meanwhile, regarding the first example, although the initial properties were sufficient, in terms of durability both the residual polarization and piezoelectric constant are degraded after applied voltage at 10¹⁰ times. That is, the resistance to voltage was 101V, residual polarization was 44 μC/cm², piezoelectric constant was −140 pm/V, and degradation rate (%) of ink drop speed was 11.2%.

### Third Embodiment

FIG. 5 shows an ink cartridge 80 according to a third embodiment comprising the ink jet head (fluid discharge head) of the second embodiment.

The ink cartridge 80 comprises a fluid discharge head 100 with a nozzle 81 and an ink tank 82 integrated with each other. The ink tank 82 contains ink in advance and supplies the ink to the fluid discharge head 100.

The fluid discharge head 100 is the ink jet head 20 of the second embodiment in FIG. 3 and includes the piezoelectric actuator 10 of the first embodiment 10 in FIG. 2 as a piezoelectric element.

In such a fluid discharge head 100 integrated with the ink tank 82, the yield and reliability of the ink cartridge 80 can be improved by the precise, highly dense, and reliable actuator. Thus, the cost reduction of the ink cartridge 80 can be achieved.

According to the present embodiment, the ink cartridge 80 comprising the ink jet head excelling in durability and reliability can be realized.

### Fourth Embodiment

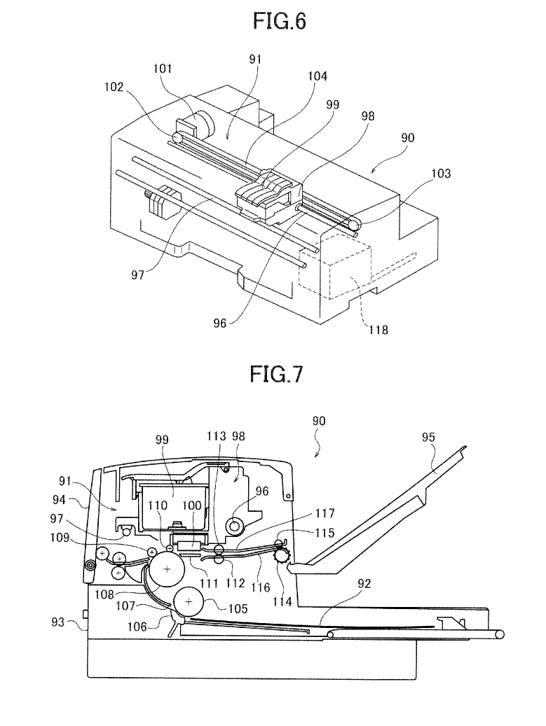

FIGS. 6 and 7 show an image forming device 90 according to a fourth embodiment which comprises the ink jet head of the second embodiment and the ink cartridge of the third embodiment.

The image forming device 90 comprises a carriage 98 movable in a scanning direction inside a device body and a printing unit 91 including the fluid discharge head 100 mounted on the carriage 98 and an ink cartridge 99 to supply ink to the fluid discharge head 100.

A paper cassette or tray in which a large number of paper sheets 92 are set from the front is detachably provided in the bottom part of the device body. A manual paper tray 94 on which paper sheets are manually set is also provided. The paper sheets 92 are fetched from the paper cassette 93 or manual paper tray 94, a desired image is recorded thereon by the printing unit 91, and discharged to a discharge tray 95 at the back.

The printing unit 91 includes a main guide rod 96 and a sub guide rod 97 extending between not-shown right and left side plates to slidably hold the carriage 98 in a main scanning direction. The carriage 98 is provided with the fluid discharge heads 100 to discharge ink drops of four colors, yellow (Y), cyan (C), magenta (M), and black (Bk), respectively. In the carriage 98 discharge ports (nozzles) to discharge the ink downward are arranged orthogonally to the main scanning direction. Ink cartridges 99 are detachably mounted on the carriage 98 to supply the four-color ink to the fluid discharge heads 100.

The ink cartridges 99 each include an air port on the top in communication with the atmosphere and a supply port on the bottom to supply the ink to the fluid discharge heads 100. The ink cartridges 99 contain a porous element filled with the ink so that it is able to maintain the ink at a very small negative pressure by a capillary force of the porous element. The present embodiment uses four fluid discharge heads to discharge the four-color ink drops. However, a single fluid discharge head with nozzles to discharge the four-color ink drops can be used.

The back side (downstream of paper feed direction) of the carriage 98 is slidably supported by the main guide rod 96 and the front side (upstream of paper feed direction) thereof is slidably supported by the sub guide rod 97. The carriage 98 is provided with a main scan motor 101, a drive pulley 102, a driven pulley 103, and a timing belt 104 which extends between the drive pulley 102 and driven pulley 103. The carriage 98 is secured on the timing belt 104. The main scan motor 101 regularly or reversely rotates the drive pulley 102 to reciprocate the timing belt 104, thereby moving the carriage 98 in the main scanning direction.

To feed the paper sheets 92 downward from the paper cassette 93 to below the fluid discharge heads 100, a paper feed roller 105, a friction pad 106, a guide element 107, a conveying roller 108, a conveying roller 109, and an end roller 110 are provided. The paper feed roller 105 and friction pad 106 separate the paper sheets 92 from the paper cassette 93. The guide element 107 guides the separated paper sheets to the conveying roller 108 and the conveying roller 108 inversely rotates the paper sheets 92. The convey roller 109 is pressed onto the circumference of the conveying roller 108 and the end roller 110 is provided to define the angle at which the papers is sent fourth from the conveying roller 108. The conveying roller 108 is rotated by a not-shown sub scan motor via a gear train.

Further, a paper receiver Ill is provided below the fluid discharge head 100 to guide the paper sheets from the convey roller 108 in accordance with a moving range of the carriage 98 in the main scanning direction. A roller 112 and a gear 113 are provided at downstream of the paper receiver 111 in the paper feed direction to be rotated to convey the paper sheets 92 in the paper discharge direction. At downstream of the roller 112 and gear 113, a discharge roller 114 and a gear 115 to discharge the paper sheets 92 to the paper discharge tray and guide elements 116, 117 forming a paper discharge path are disposed.

The image forming device 90 drives the fluid discharge heads 100 in accordance with an image signal while moving the carriage 98, to discharge ink to a still paper sheet 92 and records one line of an image thereon. Then, it moves the paper sheet 92 by a certain amount and record a next line of the image. Upon receiving a recording stop signal or a signal indicating that the rear end of the paper sheet 92 has reached a recording area, it completes a recording operation and discharges the paper sheet 92.

Moreover, a recovery unit 118 is provided outside the recording area at the right end of the moving direction of the carriage 98, to resolve a discharge failure of the fluid discharge heads 100. The recovery unit 118 comprises a cap, a cleaner, and a suction element. The carriage 98 is moved to the end near the recovery unit during a print standby and the fluid discharge heads 100 are covered with the cap to maintain the moistness of discharge ports and prevent a discharge failure due to dried ink. Also, it is configured to discharge ink irrelevant to recording so that ink viscosities of all the discharge ports become constant. Thereby, a stable ink discharge can be maintained.

When a discharge failure occurs, the outlets (nozzles) of the fluid discharge heads 100 are sealed with the cap and the suction element sucks air bubbles and the ink through a tube. The cleaner removes the ink, dust and the like attached to the discharge ports, thereby resolving a discharge failure. The suctioned ink is discharged to a not-shown used ink tank and absorbed into an ink absorber therein.

As described above, the image forming device 90 according to the present embodiment achieves stable ink discharge properties and improve image quality since it comprises the fluid discharge heads 100 of the first embodiment.

In addition to the image forming device 90, the fluid discharge heads 100 are applicable to a device to discharge fluid other than ink, for example, fluid resist for patterning.

According to the present embodiment, a high-quality image forming device can be obtained owing to the piezoelectric thin film excelling in durability and reliability.

Although the present invention has been described in terms of exemplary embodiments, it is not limited thereto. It should be appreciated that variations or modifications may be made in the embodiments described by persons skilled in the art without departing from the scope of the present invention as defined by the following claims.

For example, the image forming device 90 according to the fourth embodiment is applicable to a printer, a facsimile machine, a copier, and a multifunction peripheral.

Further, the present invention is applicable to a fluid discharge head or fluid discharge device to discharge fluid other than ink, for example, DNA specimen, resist, or patterning material as well as to an image forming device incorporating such a head or device.

What is claimed is:

1. A piezoelectric actuator comprising:
a vibrating plate;
a lower electrode provided on the vibrating plate, including a platinum film and a titanium oxide film formed on the platinum film;
a piezoelectric thin film provided on the lower electrode; and
an upper electrode provided on the piezoelectric thin film, wherein
the titanium oxide film is provided between the platinum film and the piezoelectric thin film.

2. The piezoelectric actuator according to claim 1, further comprising
a titanium oxide adherent layer formed on the vibrating plate, wherein
the platinum film is provided on the titanium oxide adherent layer.

3. The piezoelectric actuator according to claim 1, wherein
the piezoelectric thin film is a PZT film with a crystallinity (100).

4. The piezoelectric actuator according to claim 1, wherein
a thickness of the titanium oxide film is from 50 to 100 angstrom.

5. The piezoelectric actuator according to claim 2, wherein
a thickness of the titanium oxide adherent layer is from 20 to 50 nm.

6. A fluid discharge head comprising:
a nozzle to discharge fluid drops;
a pressure chamber communicating with the nozzle; and
the piezoelectric actuator according to claim 1, to apply pressure to fluid in the pressure chamber and discharge fluid drops from the nozzle.

7. A cartridge comprising:
the fluid discharge head according to claim 6; and
a tank to supply fluid to the fluid discharge head, wherein
the fluid discharge head and the tank are integrated.

8. An image forming device comprising the fluid discharge head according to claim 6.

9. An image forming device comprising the cartridge according to claim 7.

10. A manufacturing method of a piezoelectric actuator comprising a vibrating plate, a lower electrode provided on the vibrating plate, including a platinum film and a titanium oxide film formed on the platinum film, a piezoelectric thin film provided on the lower electrode, and an upper electrode provided on the piezoelectric thin film, the method comprising:
forming a titanium film on the platinum film; and
thermally oxidizing the titanium film by rapid thermal annealing to form the titanium oxide film.
